(19) United States
(12) Patent Application Publication
(10) Pub. No.: US 2013/0148447 A1
(43) Pub. Date: Jun. 13, 2013

(54) Reducing Power Consumption in a Memory System

(71) Applicants: Ian P. Shaeffer, Los Gatos, CA (US); Jared L. Zerbe, Woodside, CA (US); Frederick A. Ware, Los Altos Hills, CA (US)

(72) Inventors: Ian P. Shaeffer, Los Gatos, CA (US); Jared L. Zerbe, Woodside, CA (US); Frederick A. Ware, Los Altos Hills, CA (US)

(21) Appl. No.: 13/707,540

(22) Filed: Dec. 6, 2012

Related U.S. Application Data
(60) Provisional application No. 61/567,795, filed on Dec. 7, 2011.

(51) Int. Cl. G11C 5/14

(52) U.S. Cl. CPC G11C 5/14
USPC 365/189.17

(57) ABSTRACT

Components of a memory system, such as a memory controller or memory device, that operate in different power states to reduce the overall power consumption of the memory system. In some of the power states, distribution circuitry that distributes a timing signal within the components may be powered on when the output of the distribution circuitry is needed. In other power states, the distribution circuitry may be powered off when the output of the distribution circuitry is not needed. Additionally, power states in the memory device may be triggered off memory access commands issued by the memory controller.

### CROSS REFERENCE TO RELATED APPLICATIONS

This application claims priority from U.S. Patent Application No. 61/597,795, filed on Dec. 7, 2011, the contents of which are incorporated by reference herein in their entirety.

### BACKGROUND

The present disclosure relates to memory systems and related components used in such system. Power consumption is a constraint on computing devices due to factors such as power density limits and limited power availability (in, for example platforms based on battery-operated portable devices) and limited heat dissipation limits for systems such as servers. In many computing devices the memory system may contribute to a sizeable amount of power consumed by the device. As computing devices are made faster, the power requirements may increase since the memory subsystem consumes more power and generates more heat as system clock rates increase.

### BRIEF DESCRIPTION OF THE DRAWINGS

The teachings of the embodiments herein can be readily understood by considering the following detailed description in conjunction with the accompanying drawings.

FIG. 1 is a multi-rank memory system, according to an embodiment.

FIG. 2 is an expanded view of the memory controller and a single memory device from FIG. 1, according to an embodiment.

FIG. 3A is a timing diagram of power states for the memory controller and memory device from FIG. 2, according to an embodiment.

FIG. 3B is a timing diagram of power states for the multi-rank memory system of FIG. 1, according to an embodiment.

FIG. 4 is an expanded view of the memory controller and a single memory device from FIG. 1, according to another embodiment.

FIG. 5 is a state table of the various power states supported by the memory controller and memory device of FIG. 4, according to an embodiment.

FIG. 6A is a timing diagram of power states for the memory system of FIG. 1 and FIG. 4, according to an embodiment.

FIG. 6B is a timing diagram of power states for the memory system of FIG. 1 and FIG. 4, according to another embodiment.

FIG. 6C is a timing diagram of power states for the memory system of FIG. 1 and FIG. 4, according to still another embodiment.

FIG. 7 is an expanded view of the memory controller and a single memory device from FIG. 1, according to another embodiment.

FIG. 8A is a more detailed view of the power domains of a memory device, according to an embodiment.

FIG. 8B is a more detailed view of the power domains of a memory controller, according to an embodiment.

FIG. 9 is a circuit diagram of a bias supply circuit that enables fast turn on of the power domains described herein, according to an embodiment.

### DETAILED DESCRIPTION OF EMBODIMENTS

Embodiments of the present disclosure relate to components of a memory system that may operate in different power modes to reduce the overall power consumption of the system. In one embodiment, the system includes a memory device and a memory controller that support multiple power states. The memory device includes interface circuitry for transferring data between a memory core of the memory device and one or more ports of the memory device. The memory device also includes timing distribution circuitry that distributes a timing reference signal (e.g. a clock signal) to the interface circuitry and control circuitry that powers on the timing distribution circuitry based on a memory access command (e.g., a row or column access command). Selectively powering on the distribution circuitry reduces the power consumption of the memory device when data is not being transferred and the output of the distribution circuitry is not needed.

In some embodiments, the memory controller also includes interface circuitry for transferring data between a control circuit of the memory controller and one or more ports of the memory controller and timing distribution circuitry that distributes a timing reference signal to the interface circuitry. The controller powers on the timing distribution circuitry when data is being transferred during memory access operations but powers off the timing distribution circuitry when no data is being transferred to reduce power consumption.

As used herein, “timing reference signal” is used generically to refer to any signal that can be used as a timing reference. Examples of timing reference signals include data strobe signals, external clocks, and internally generated clocks. In some embodiments, synchronous logic circuits (e.g., flip-flops, state machines, etc) may use a timing reference signal as a reference in reading in input values or changing the state of output values. In one embodiment, a port may refer to a portion of a component through which external communications with other components is made.

Reference will now be made in detail to several embodiments of the present disclosure, examples of which are illustrated in the accompanying figures. It is noted that wherever practicable similar or like reference numbers may be used in the figures and may indicate similar or like functionality. The figures depict embodiments of the present disclosure for purposes of illustration only. One skilled in the art will readily recognize from the following description that alternative embodiments of the structures and methods illustrated herein may be employed without departing from the principles, or benefits touted, of the disclosure described herein.

### System Overview

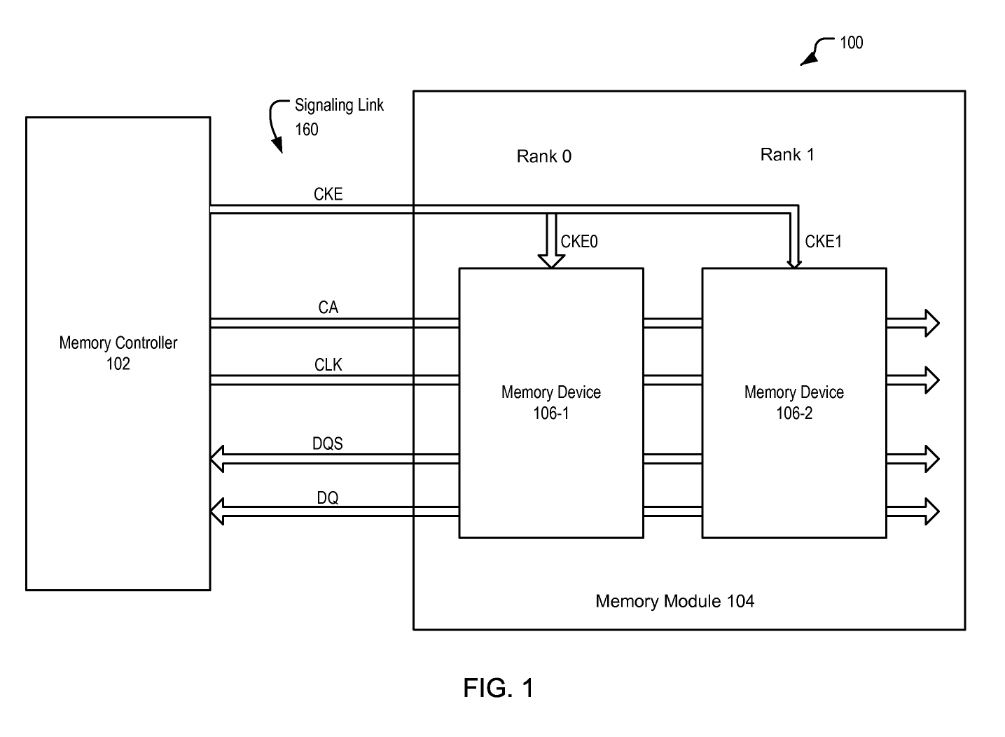

FIG. 1 is a memory system 100, according to one embodiment. The memory system 100 includes a memory controller 102 and a memory module 104 interconnected via a signaling link 160. The memory module 104 includes two memory devices 106-1 and 106-2. In one embodiment, system 100 may reside on a motherboard. The memory controller 102 may be a chip that is capable of controlling memory devices 106. Examples of a memory controller 102 include a central processing unit (CPU), a graphics processing unit (GPU), a system on chip (SoC), etc.

Both the memory controller 102 and the memory device 106 support different power states to reduce the amount of power consumed by the memory system 100. During the various power states, power domains within the memory devices 106 or the memory controller 102 may be powered on by supplying the power domains with a source of power. The power domains may be powered off by removing the source of power from the power domains. In one embodiment, one or more bias voltages serve as the source of power. One or more bias circuits (not shown) generate the bias voltages and are able to quickly power on the power domains within a short amount of time.

In one embodiment, one or more power states in the memory devices 106-1 are triggered by memory access commands sent by the memory controller 102. In one embodiment, one or more power states in the memory device 106-1 are triggered by an external clock enable (CKE) signal sent by the memory controller 102. In one embodiment, the memory controller 102 controls its own power states based on whether data is being accessed or commands are being transferred.

The memory module 104 includes two memory devices 106-1 and 106-2 that are organized into memory ranks Memory device 106-1 is in Rank 0, and memory device 106-2 is in Rank 1. Each rank of memory devices 106 is independently addressable from the other ranks of memory devices 106. In other embodiments, there may be multiple memory devices 106 in a single memory rank. Additionally, there may be more than two ranks of memory devices 106 in a single memory module 104. In other embodiments, the system 100 may include multiple memory modules 104, each having one or more ranks of memory devices 106.

The signaling link 160 includes a command and address link CA, a clock link CK, a data strobe link DQS, a data link DQ, and a clock enable link CKE. CA link carries memory access commands and other control information from the memory controller 102 to the memory devices 106 on memory module 104. In one embodiment, the memory controller 102 initiates a memory access operation by transmitting a row access command that activates a row of the memory device 106 for the memory access. The row access command is then followed by a column access command. The column access command also specifies whether the memory access operation is a read operation that reads data from the memory device 106 or a write operation that writes data to the memory device 106.

The CLK link carries a clock signal from the memory controller 102 to the memory module 104 that is used as a timing reference for transferring commands via the CA link. The DQS link carries a data strobe signal that is used as a timing reference for transferring data during memory access operations. The DQ link carries data signals to and from the memory module 104 during memory access operations. The CKE link carries a CKE0 signal for the memory devices 106-1 in Rank 0, and a CKE1 signal for the memory devices 106-2 in Rank 1.

In some embodiments, the signaling link 160 may carry signal ended signals, differential signals, or a mix of single ended and differential signals.

### Memory Controller and Memory Device

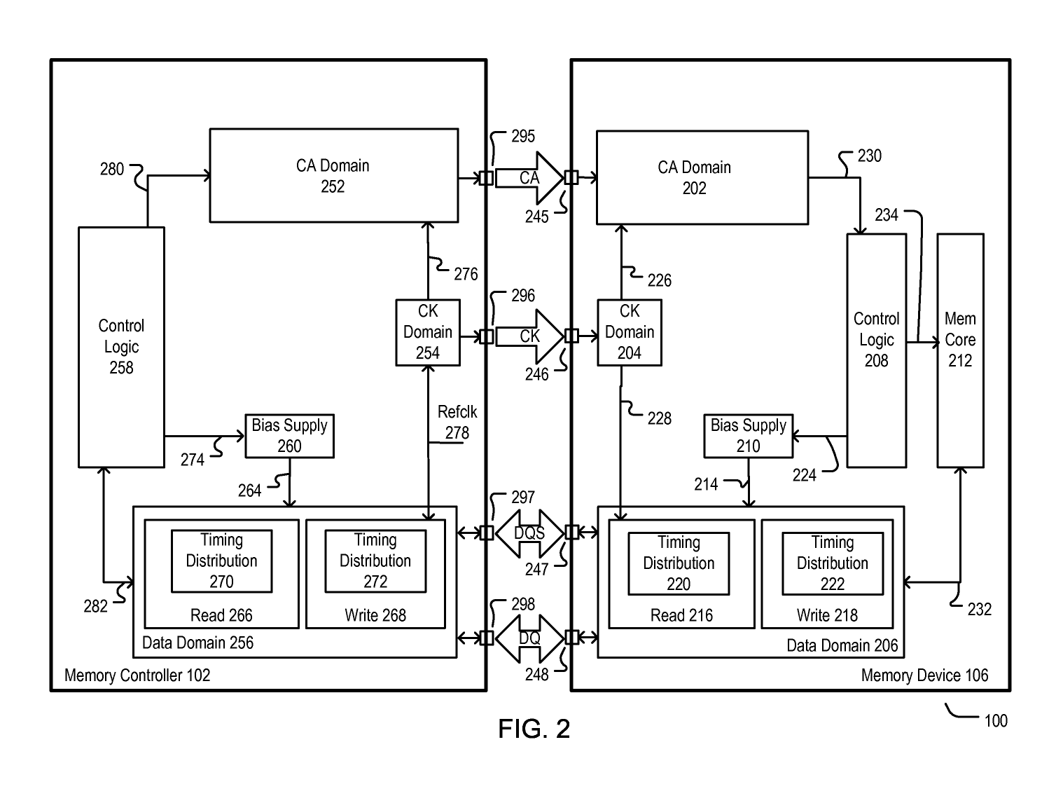

FIG. 2 is an expanded view of the memory controller 102 and a single memory device 106 from FIG. 1, according to an embodiment. The memory device 106, in an embodiment, includes blocks that operate according to specific power domains: CA power domain 202, CK power domain 204, and Data power domain 206. As will be explained in the different embodiments, the memory device 106 supports different power states so that different power domains may be selectively powered on at different times to reduce the power consumption of the memory device 106.

The data power domain 206 includes circuitry that supports transfer of data (e.g. read data or write data) between the data port(s) 248 and the memory core 212 during memory access operations. The data power domain 206 interfaces with the DQ link via data port(s) 248 and DQS link via port(s) 247 to transfer data and data strobe signals with the memory controller 102. The data power domain 206 also transfers data with the memory core 212 via signaling path 232. Additionally, the data power domain 206 receives a bias supply voltage 214 that provides power to the circuitry within the data power domain 206.

The data power domain 206 can further be divided into a read power domain 216 and a write power domain 218. The read domain 216 includes circuitry that is used during read operations to convey data read from the memory core 212 to the data ports 248 of the memory device 106. The read power domain 216 includes a timing distribution circuit 220 that distributes a clock signal within the memory device 106 during read operations. In one embodiment, the timing distribution circuit 220 may distribute clock signal 228 to read interface circuitry (not shown) that temporarily stores the data read from the memory core 212. The read interface circuitry then outputs the data to the DQ link via data ports 248.

The write power domain 218 includes circuitry that is used during write operations to receive write data from the DQ link and to convey the data to the memory core 212. The write power domain 218 includes a timing distribution circuit 222 that distributes a clock signal within the memory device 106 during write operations. In one embodiment, the timing distribution circuit 222 may receive a data strobe signal from the DQS link via ports 247 and distribute the signal to write interface circuitry (not shown). The write interface circuitry temporarily stores write data received from the DQ link via data ports 248 and then outputs the data to the memory core 212 so that the data can be stored.

Generally speaking, timing distribution circuits (e.g., 220 and 222) accept a timing reference signal (e.g., clock or data strobe) as an input and distribute the timing reference signal to interface circuits that use the clock signal as a timing reference in transferring data during a memory access operation. Timing distribution circuits may also be referred to as clock distribution circuits or clock trees. In one embodiment, the timing distribution circuits include clock buffers. In other embodiments, the timing distribution circuits include digital controlled delay lines (DCDL) that are inserted in series with the clock buffers.

Embodiments of the present disclosure selectively power down the timing distribution circuitry when the timing distribution circuitry is not needed, thereby reducing the power consumption of the memory system 100. In one or more embodiments, the timing distribution circuits 220 and 222, as well as other circuitry in the power domains, utilize current mode logic (CML). CML is a differential current-mode-logic signaling scheme that employs low voltage swings (and thus typically benefit from differential noise immunity to achieve high signaling speeds). CML circuits can consume more DC power than CMOS circuits. However, this problem is alleviated when the CML circuits are used in conjunction with the bias supply circuit 210. According to embodiments, the bias supply circuit 210 switches the CML circuits between a power-on state that consumes power and a power-off (non-functional) state that consumes zero or substantially less power. Hence, when no data is being transferred, the power consumed by the timing distribution circuits 220 and 222 can be completely turned off, and very little DC power is consumed by the timing distribution circuits 220 and 222. On the other hand, when data is being transferred, the timing distribution circuits 220 and 222 can be powered on. Integrating a switchable bias supply 210 with the timing distribution circuits 220 and 222 thus achieves both low overall power consumption and high noise rejection in a given clock path.

The CK power domain 204 includes circuitry that interfaces with and receives an external clock signal from the CK link via clock port(s) 246. The CK power domain 204 then outputs a clock signal 226 to the CA power domain 202 for use as a timing reference in receiving incoming commands and address signals. CK power domain 204 also outputs a clock signal 228 to the data power domain 206 for use as a timing reference during read operations.

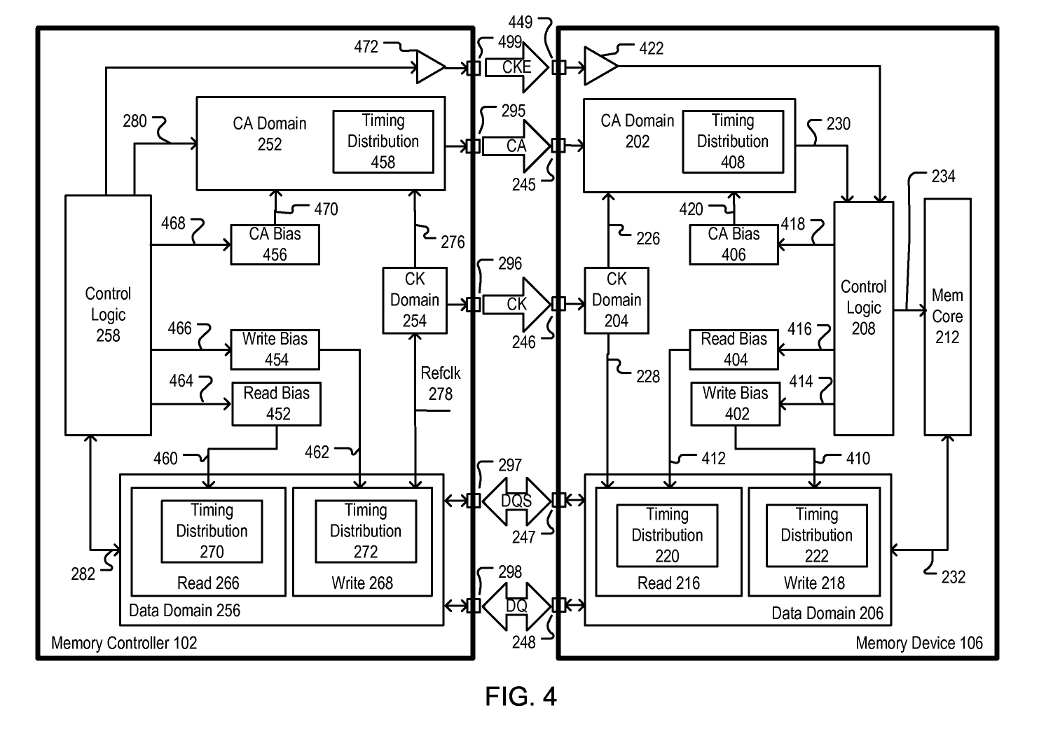

The CA power domain 202 includes circuitry that supports transfer of CA information, such as commands and other control information, from the CA port(s) to the control logic 208. In one embodiment, the CA power domain 202 receives CA signals from the memory controller 102 via the CA link and temporarily stores the CA signals before outputting the commands to the control logic 208 via signaling path 230. As will be explained by reference to FIG. 4-7, in some embodiments the CA power domain 202 and/or CK power domain 204 may also be powered off to reduce power consumption of the memory device 106.

Control logic 208 decodes incoming memory access commands and generates a control signal 224 that controls the bias supply circuit 210 by enabling or disabling the bias supply circuit 210. In embodiments, certain memory access commands may have information encoded to cause the control logic 208 to enable the bias supply circuit 210. In other embodiments, certain memory access commands directly cause the control logic 208 to enable the bias supply circuit 210. In some embodiments, the control logic 208 enables the bias supply 210 circuit if the memory access command requests access to a column address. In some embodiments, the control logic 208 enables the bias supply 210 circuit if the memory access command requests access to a row address. Enabling the bias supply circuit 210 powers on the bias voltage 214, thereby powering on the data domain 206.

In an embodiment, once the memory access operation is completed (i.e., data transfer is complete) and the data domain 206 is no longer needed, the control logic 208 then disables the bias supply circuit 210 to conserve power. In one embodiment, the control logic 208 disables the bias supply circuit 210 if it receives a pre-charge command that de-activates a row of the memory core 212. In another embodiment, the control logic 208 automatically disables the bias supply circuit 210 if no other memory access commands are received within some pre-determined amount of time after the memory access command. In another embodiment, the memory access command that initiated the memory access operation may be encoded with an indication that auto-power down is enabled, such as through an auto-power down bit. If the power down bit indicates that auto-power down is enabled, the control logic 208 automatically disables the bias supply 210 after the data for the memory access operation is transferred.

The bias supply circuit 210 generates a bias supply voltage 214 based on the status of control signal 224. The control signal 224 may be an enable signal that powers on the bias supply voltage 214 when asserted, and powers off the bias supply voltage 214 when de-asserted. In one embodiment, the bias supply circuit 210 is a bias circuit that is capable of powering on a bias voltage in just a few clock cycles. By powering on the bias voltage 214 within a short amount of time, the data domain 206 can be powered on in response to data access commands without affecting the response latency of the memory device 106. As a result, the data domain 206 (including, e.g., the timing distribution circuitry 220 and 222) can be selectively powered off when data is not being transferred to reduce the power consumption of the memory device 106.

In an embodiment, memory core 212 includes memory cells for storing data and is organized into rows and columns. During memory access operations, the core 212 receives decoded row and column addresses from the control logic 208 via signaling path 234. During read operations, data is provided from the memory core 212 to the read domain 216 for transmission to the memory controller 102. During write operations, data is provided by the write domain 218 to memory core 212 for storage in the memory core 212. Memory core 212 may include any type of memory, such as dynamic random access memory (DRAM), non-volatile memory (NVM), or static random access memory (SRAM).

Referring to the memory controller 102, in accordance with one or more embodiment, the memory controller 102 includes circuits that operate in different power domains: CA power domain 252, CK power domain 254, and data power domain 256. As will be explained in the different embodiments, the memory controller 106 also supports different power states so that different power domains may be selectively powered on at different times to reduce the power consumption of the memory controller 106.

The data power domain 256 includes circuitry that supports transfer of data between the control logic 258 and the data port(s) 298 during memory access operations. The data power domain interfaces with the DQ links via port(s) 298 and DQS links via ports 297 to transfer data and data strobe signals with the memory device 106. During the memory access operations, the data power domain 256 also transfers data with the control logic 258 via signaling path 282. Additionally, the data power domain 256 receives a bias supply voltage 264 that provides power to the circuitry within the data power domain 256.

The data power domain 256 can further be divided into a read power domain 266 and a write power domain 268. The read domain 266 includes circuitry that is used during read operations to receive data from the memory device 106 via the DQ link and to convey the read data to the control logic 258. The read power domain 266 includes a timing distribution circuit 270 that distributes a timing reference signal within the memory controller 102 during read operations. In one embodiment, the timing distribution circuit 270 may distribute a data strobe signal received from the DQS link via port(s) 297 to interface circuitry (not shown). The interface circuitry temporarily stores data from the DQ link before outputting the data to the control logic 258.

The write power domain 268 includes circuitry that is used during write operations to receive write data from the control logic 258 and to convey the write data to the DQ link via port(s) 298. The write power domain 268 includes a timing distribution circuit 272 that distributes a clock signal within the memory controller 102 during write operations. In one embodiment, the timing distribution circuit 270 may distribute reference clock (refclk) 278 to interface circuitry (not shown) that temporarily stores write data during write operations. The data is then output to the DQ link via data port(s) 298. In one embodiment, the timing distribution circuits 270 and 272 include buffers and/or DCDL circuits and may use CML logic.

The CK power domain 254 interfaces with the CK link via port(s) 295 to output an external clock signal. In one embodiment, the CK power domain 254 receives a reference clock 278 and then multiplies the clock to generate a faster clock 276. For example, Refclk 278 may be a 200 MHz clock which is converted into a 1 GHz clock 276. The CK domain 254 may output the faster clock 276 to the CA domain 252 for use as a timing reference in outputting commands from the memory controller 102. The CK power domain 254 may also output the faster clock via the CK link.

The CA power domain 252 includes circuitry that supports transfer of CA signal from the control logic 258 to the CA port(s) 295. In one embodiment, the CA power domain 252 receives CA signals from the control logic 258 and temporarily stores the CA signals before outputting the CA signals to the memory device 106.

Control logic 258 initiates memory access operations by generating outgoing memory access commands that are transmitted to the CA domain 252. During memory access operations, the control logic 258 transfers data with the data domain circuitry 256 via signal path 282. The control logic 258 also generates a control signal 274 that controls the bias supply circuit 260 and enables or disables the bias supply circuit 260. The bias supply circuit 260 generates a bias supply voltage 264 based on the status of control signal 274. Generally speaking, the control logic 258 enables the bias supply circuit 260 during data operations while disabling the bias supply circuit 260 when data operations are concluded. Enabling the bias supply circuit 260 powers on the bias voltage 264, thereby powering on the data domain 256. By disabling the bias supply circuit 260 when data is not being transferred, the power consumption attributed to the circuits in the data power domain 256 can be reduced.

In some embodiments, the control logic 256 determines whether data is about to be transferred during a memory access operation and enables the bias supply circuit 260 prior to the transfer of data. Certain events may cause the control logic 258 to determine that data is about to be transferred. For example, the issuance of a memory access command may be an indication that data is about to be transferred. Control logic 258 then enables the bias supply 260 circuit within a pre-determined amount of time after issuing the memory access command. The pre-determined amount of time may be set, for example, to coincide with the read or write latency of the memory device 106 so that the data domain 256 is ready to transfer data when the memory device 106 is ready to transfer data. As another example, control logic 256 may maintain a queue of pending memory access operations and enable the bias supply circuit whenever the queue is not empty.

The control logic 258 may also disable the bias supply circuit 260 after determining that the data transfer is complete and the data domain 266 is no longer needed. In one embodiment, the bias supply circuit 260 may be disabled after a data burst associated with a memory access operation (e.g., read or write) is complete and there are no further pending memory transactions of that type that have been issued to memory device 102. In one embodiment, the control logic 258 may disable the bias supply circuit 260 within a pre-determined amount of time after issuing a command (e.g., read, write, or pre-charge command). The time may be approximately equal to the memory latency plus the data burst length.

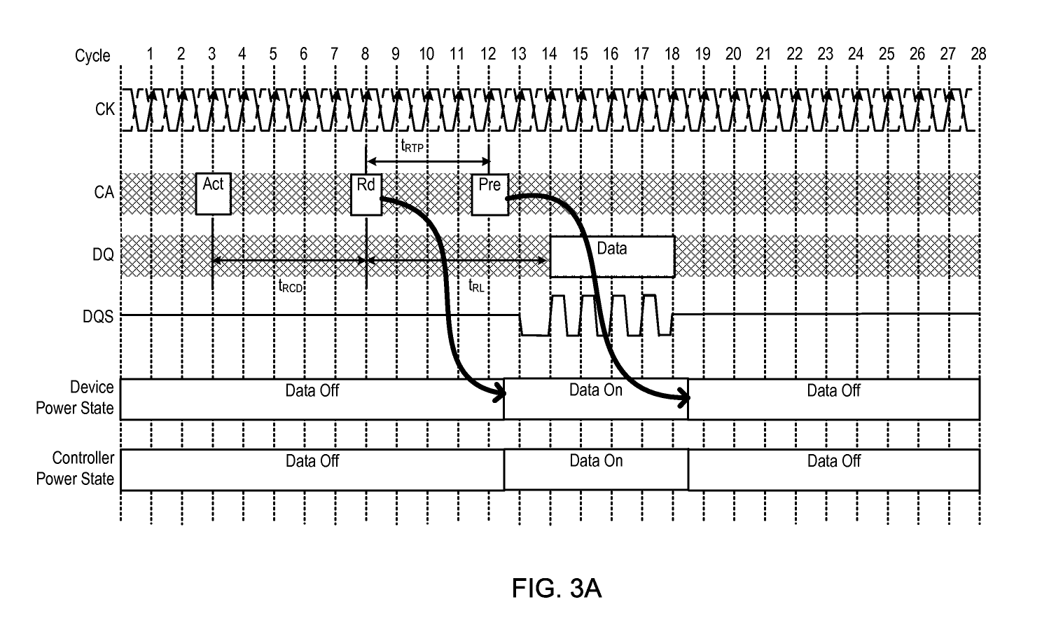

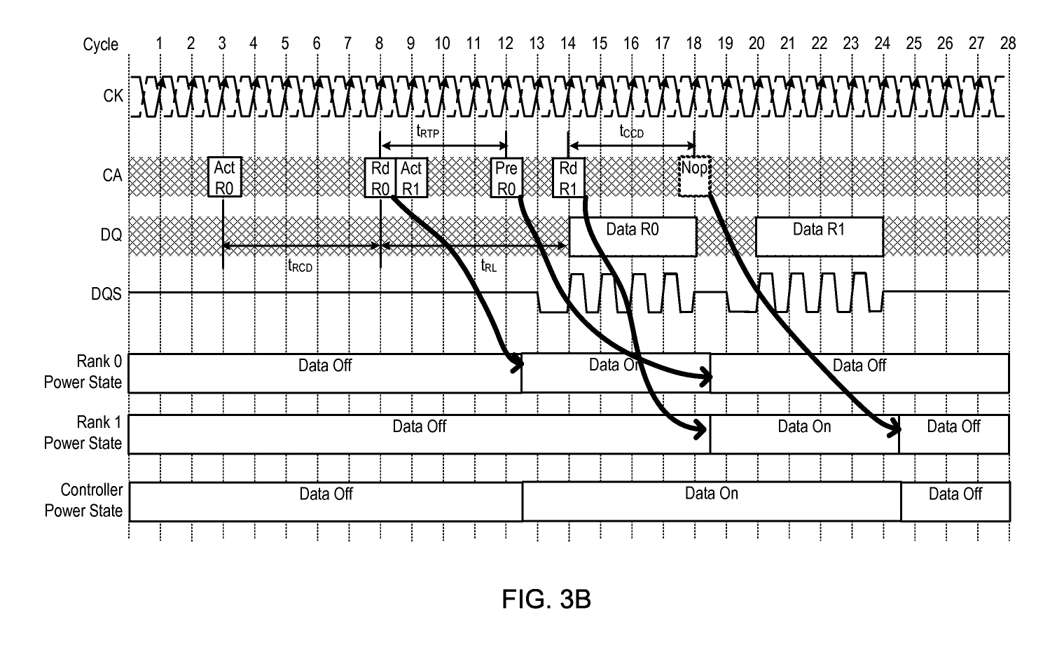

FIG. 3A is a timing diagram of power states for the memory system 100 of FIG. 2, according to an embodiment. Referring to the device 106 power state, initially in cycle 1, the memory device 106 is in a low power state and the data power domain 206 is powered off. In cycle 3, the memory controller 102 issues an activate (Act) command to access a row address of the memory device 106. In cycle 8, after the expiration of the Row-to-Column Delay (t_{RCD}) time, the memory controller 102 issues a read (Rd) command to read data from a column address of the memory device 106. The t_{RCD} time specifies the amount of time needed for the memory device 106 to open the row address specified by the Act command.

The Rd command triggers the control circuit 208 to enable the bias supply circuit 210, thereby powering on the data domain 206 by cycle 13. In one embodiment, the Act command may be used as the trigger for enabling the bias supply circuit 210 instead of the Rd command. In another embodiment, the Rd command may be a posted column command. A posted column command is a column command that is issued prior to the expiration of the t_{RCD} time, and would appear on the CA link sometime between cycles 4-7. The control circuit 208 may also use the posted column command as a trigger for enabling the bias supply circuit 210. In embodiments where the memory access operation is a write operation instead of a read operation, a write (Wr) command would cause the control circuit 208 to enable the bias supply circuit 210.

The bias supply circuit 210 is able to power on the data domain 206 prior to the expiration of the read latency time (t_{RL}). This allows the data domain 206 to be selectively powered on and off to reduce power consumption without increasing the latency of the memory access. In one embodiment, the control circuit 208 is configured to wait for a pre-determined amount of time after receiving a memory access command before enabling the bias supply circuit 210. For example, the control circuit 208 could enable the bias supply circuit 210 anytime between cycles 9-12, so long as the data domain 206 is powered on in time for the pre-amble on the strobe signal, which in FIG. 3A begins one clock cycle prior to the expiration of t_{RL}.

During cycles 14-18, the data power domain 206 receives data from the memory core 212 and transmits the data via the DQ link. In embodiments that involve a write operation, the data power domain would receive data via DQ link and write the data to the memory core 212 instead.

The precharge (Pre) command at cycle 12 triggers the control circuit 208 to disable the bias supply circuit 210 in cycle 19, thus powering down the data domain 206. The Pre command closes the row of the memory device that was opened by the Act command and is issued within a row precharge (t_{RTP}) delay time after the Rd command. Assuming that no rows remain open after the Pre command is executed, data cannot be transferred until another Act command is issued that opens a new row of memory. Opening a new row of memory consumes several clock cycles. Thus, the data domain 206 can thus be powered off when no rows are open to conserve power until the data domain 206 is needed again.

In other embodiments, the Rd command includes an explicit auto-power down bit. If the auto power-down bit indicates that auto power-down is enabled, the control circuit 208 automatically powers down the data domain 206 after the data transmission is complete (e.g., at clock cycle 19). In yet another embodiment, if no additional memory access command for the memory device 106 is received within a pre-determined amount of time after the Rd command, the control circuit 208 automatically powers down the data domain 206 once the data transfer is complete. For example, if the Pre command were missing at cycle 12, and there were no column commands at cycles 12 or 13, this also causes the control circuit 208 to power down the data domain 206 as early as at cycle 18. In one embodiment, the pre-determined amount of time may be stored in a programmable register of the memory device 102, and can be programmed with received from the memory controller 106. In other embodiments, different indications may be used by the control circuit 208 as a trigger for powering down the data domain 206.

Referring to the power states for the memory controller 102, the power states of the memory controller 102 are similar to the power states of the memory device 106. Initially in cycle 1, the memory controller 102 is in a low power state and the data power domain 256 is powered off. At cycle 8, the memory controller 102 issues the Rd command to read data from a column address of the memory device 106. Prior to or at cycle 13, the control logic 258 enables the bias supply 260 so that the data domain 256 is powered on by cycle 13 and ready to transfer data. In some embodiments, the control logic 258 powers on the data domain 256 in response to issuance of the Rd command or other memory access command such as the Act command. In embodiments where the memory access operation is a write operation instead of a read operation, a Wr command would be issued in place of the Rd command.

During cycles 14-18, the controller 102 receives data via the DQ link. After the data transfer is complete, the control logic 258 powers down the data domain 256 in cycle 19, thus returning the controller 102 to a low power state during cycles 19-28.

In FIG. 3A, the timing of the power states of the memory device 106 are shown to match the timing of the power states of the memory controller 102. However, in other embodiments the power states may not exactly match because the controller 102 and device 106 are each responsible for controlling their own power states.

FIG. 3B is a timing diagram of power states for the multi-rank memory system 100 of FIG. 1, according to an embodiment. FIG. 3B is similar to FIG. 3A, but now adds timing information for a second rank of memory devices.

Referring first to Rank 0, in cycle 1, the data domain 206 of Rank 0 is powered off. In cycle 3, an activate (Act R0) command is issued to Rank 0 that activates a row address in Rank 0. In cycle 8, a read command (Rd R0) is issued to Rank 0, which triggers the data domain 206 of Rank 0 to be powered on by cycle 13. Rank 0 transmits read data (Data R0) to the memory controller 102 via the DQ link during cycles 14-18. In cycle 12, a precharge command (Pre R0) is issued to Rank 0, which causes Rank 0 to power down its data domain 206 in cycle 19 after the data transfer is complete.

Referring next to Rank 1, in cycle 1, the data domain 206 of Rank 1 is powered off. In cycle 9, an activate (Act R1) command is issued to Rank 1. In cycle 14, a read command (Rd R1) is issued to Rank 1, which triggers the data domain 206 of Rank 1 to be powered on by cycle 19. Rank 1 transmits read data (Data R1) to the memory controller 102 via the DQ link during cycles 20-24. In cycle 18, no memory access command (Nop) is issued to Rank 1 by the expiration of the column-to-column delay time (t_{CCD}). In systems that use back to back data bursts, another memory access command would be issued by the memory controller 102 at intervals defined by the t_{CCD} time. In one embodiment, the absence of the command at the expiration of t_{CCD} causes Rank 1 to power down its data domain 206 in cycle 25.

Referring next to the memory controller 106, in cycle 1, the data domain 256 of the memory controller is powered off. The data domain 256 is powered on when any rank of memory devices 106 is active because the memory controller 102 is responsible for transferring data with both ranks of memory devices 102. Thus, in cycle 13, the data domain 256 of the controller 106 is powered on to allow for the transfer of Data R0 during cycles 14-18. The data domain 256 remains powered on during cycles 19-24 because Data R1 is received from Rank 1 during cycles 19-24. It is not until cycle 25, after data transfer with both memory ranks is complete, that the data domain 256 of the controller 102 is powered down.

### Additional Power Domains in the Memory Controller and Memory Device

FIG. 4 is an expanded view of the memory controller 102 and a single memory device 106 from FIG. 1, according to another embodiment. The memory device 106 in FIG. 4 is similar to the memory device 106 from FIG. 2, but now includes a write bias circuit 402, a read bias circuit 404, a CA bias circuit 406, a timing distribution circuit 408 and a CKE interface 422. The memory controller 102 in FIG. 4 is also similar to the memory controller 102 from FIG. 2, but now includes a write bias circuit 454, a read bias circuit 452, a CA bias circuit 456, a timing distribution circuit 458 and a CKE interface 472.

The write bias circuit 402 and read bias circuit 404 in memory device 106 provide separate bias voltages to the read domain 216 and write domain 218, respectively. Write bias circuit 402 provides a bias voltage 410 to the write data domain 218 and is controlled by control signal 416. Read bias circuit 404 provides a bias voltage to the read data domain 216 and is controlled by control signal 414.

Control logic 208 selectively enables write bias circuit 404 or read bias circuit 402, depending on the type of memory access requested by the memory controller. If the control logic 208 receives a read access command, the control logic 208 enables the read bias circuit 404 but not the write bias circuit 402. If the control logic 208 receives a write access command, the control logic 208 enables the write bias circuit 402 but not the read bias circuit 404. Separating the bias voltages for the read domain 216 and the write domain 218 thus allows for further reduction of power consumption than is otherwise possible when both domains are powered off the same bias voltage.

Control logic 208 also disables the write bias 404 or read bias circuit 402 upon the occurrence of certain events, such as receiving a pre-charge command, receiving an auto-power down bit in a memory access command, or failing to receive an additional memory access command within a pre-determined amount of time.

The CA bias circuit 406 provides a CA bias voltage 420 to the CA domain 202. The CA bias circuit is controlled by a control signal 418 generated by the control logic 208. The CA bias circuit 406 allows for further reduction of power consumption by disabling the CA domain 202 when the CA domain 202 is not needed. As the CA domain 202 is only needed for interfacing with the CA link, the CA domain 202 can be powered down whenever the CA link is inactive and no incoming commands are expected.

The CKE interface circuitry 422 interfaces with the CKE link via port(s) 449 to receive and provide a CKE signal to the control logic 208. The control logic 208 uses the CKE signal as an indication of whether a command is likely to be received. If the CKE signal is asserted, it indicates that the CA link is active and the control logic 208 enables the CA bias circuit 406. If the CKE signal is de-asserted, it indicates that the CA link is inactive and thus the control logic 208 disables the CA bias circuit 406. In other embodiments, an external signal other than the CKE signal may be used by the control logic 208 to control the power state of the CA domain 202.

The CA domain 202 also includes a timing distribution circuit 408 that distributes a clock signal within the memory device 106 for receiving commands via the CA link. In one embodiment, the timing distribution circuit 408 distributes clock signal 226 to interface circuitry (not shown) that temporarily stores incoming command signals from the CA link via port(s) 245. The interface circuitry then conveys the command signals to the control logic 208. In one embodiment, the timing distribution circuit 408 uses CML logic.

Referring to the memory controller 102, the write bias circuit 454 and read bias circuit 452 in memory controller 102 provide separate bias voltages to the read domain 266 and write domain 268. Specifically, read bias circuit 452 provides a bias voltage 460 to the read data domain 218 and is controlled by control signal 464. Write bias circuit 454 provides a bias voltage 462 to the write data domain 268 and is controlled by control signal 466.

Control logic 258 selectively enables write bias circuit 454 or read bias circuit 452, depending on the type of memory access that is required. During read operations, the control logic 258 enables the read bias circuit 452 to power on the read domain 218 but does not enable the write bias circuit 454. During write operations, the control logic 258 enables the write bias circuit 454 to power on the write data domain 218 but does not enable the read bias circuit 452.

The CA bias circuit 456 provides a CA bias voltage 470 to the CA domain 252. The CA bias circuit 456 is controlled by a control signal 468 generated by the control logic 208. Generally speaking, the control logic 468 enables the CA bias circuit 456 to power on the CA domain 252 whenever commands are being transmitted via the CA link and disables the CA bias circuit 456 when commands are not being transmitted. The CA domain 456 is thus disabled to reduce power consumption if there are no pending commands to be transmitted to the memory devices 106 and enabled if there are pending commands to be transmitted. In one embodiment, the control logic 468 determines whether there are any pending commands to be sent to the memory device 106 and enables the CA bias circuit 456 prior to issuing the commands.

The control logic 468 also asserts a CKE signal that is provided to the CKE interface circuit 472. The CKE interface circuit 472 transmits the signal to the CKE link via port(s) 499. In one embodiment, the control logic 468 enables the CA bias circuit 456 when asserting the CKE signal, and disables the CA bias circuit 456 when de-asserting the CKE signal. The CKE signal is then used by the memory device 106 as an indication of whether a command is being transmitted.

The CA domain 252 includes a timing distribution circuit 458 that distributes a timing reference signal within the memory controller 106 for transmitting commands via the CA link. In one embodiment, the timing distribution circuit 458 may distribute clock signal 276 to interface circuitry (not shown) that temporarily stores outgoing command signals received from the control logic 258. The command signals are then transmitted onto the CA link via port(s) 295.

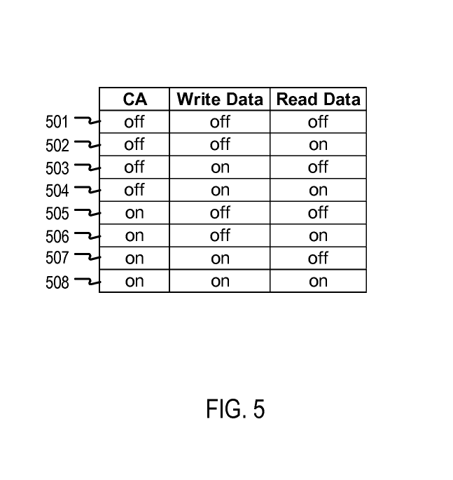

FIG. 5 is a state table of the various power states supported by the memory controller 102 and memory device 106 of FIG. 4, according to an embodiment. As shown, the memory controller 102 and memory device 106 each support up to eight different possible power states 501-508. The large number of power states is made possible by the three bias supply circuits, each of which can be enabled independently of the other bias supply circuits to optimize the power consumption of the memory system 100 by independently controlling the power on/power off status of the power domains.

Power state 501 is a low power state where the CA, write, and read domains are powered off. In power state 502, only the read domain is powered on 502. In power state 503, only the write domain is powered on. In power state 504, the CA domain is powered off and both data domains are powered on. In power state 505, only the CA domain is powered on. In power state 506, the write domain is powered off and the CA and read domains are powered on. In power state 507, the read domain is powered off and the CA and write domains are powered on. In power state 508, all three power domains are powered on.

In one embodiment, the memory controller 102 and/or memory device 106 may support only a subset of the power states shown in FIG. 5. For example, the memory device 106 may only support power states 501-503 and 505-507, but not power states 504 and 508.

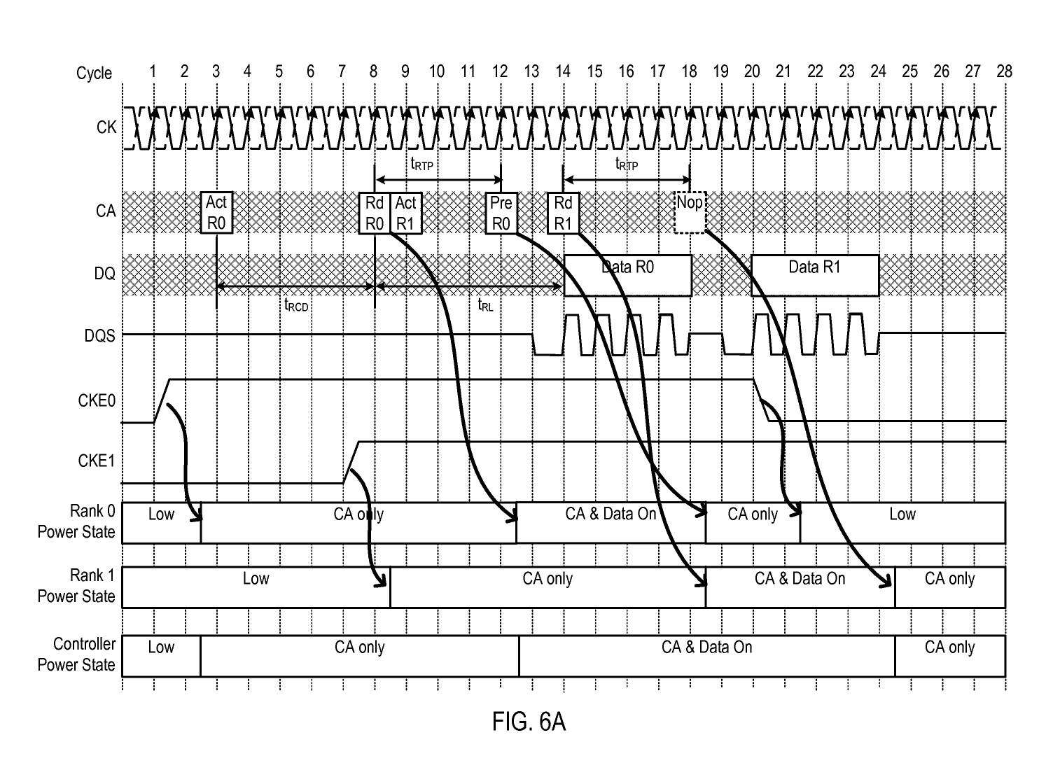

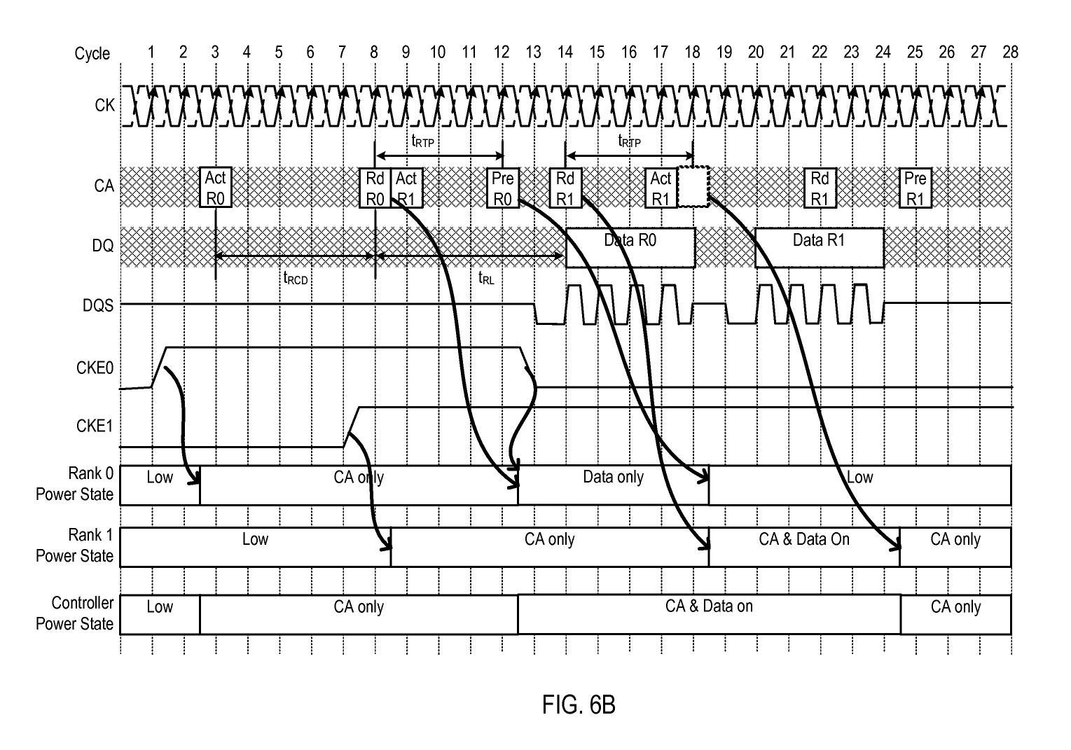

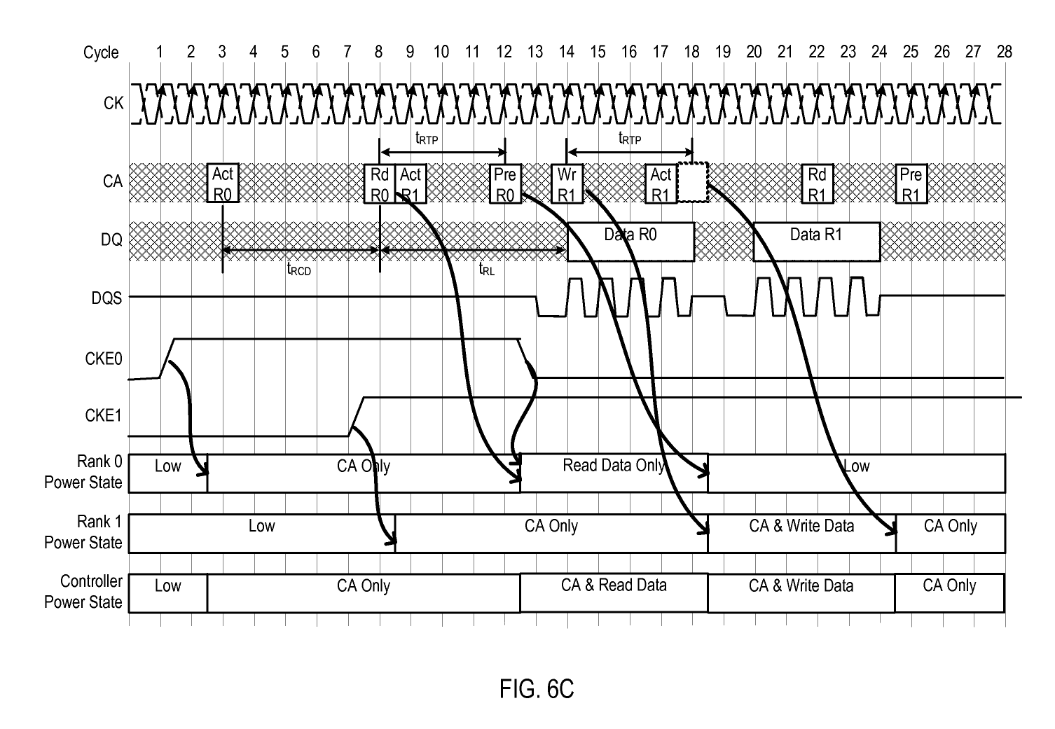

FIGS. 6A-6C are timing diagrams for a multi-rank memory system 100 where the memory controller 102 and memory devices 106 each support multiple power states, according to an embodiment. FIGS. 6A-6C are explained in conjunction with FIGS. 4 and 5.

Referring to FIG. 6A, shown is a timing diagram for a memory controller 102 and memory devices 106 that support three power states. FIG. 6A is similar to FIG. 3B, but now adds additional control for the CA power domain. As a result, the memory system now supports three power states. The “low” power state corresponds to power state 501 from FIG. 5. The “CA only” power state corresponds to power state 505 and is a power state introduced by adding a bias supply circuit 406 for the CA power domain. The “CA & Data On” power state corresponds to power state 508.

The power states for Rank 0 are first explained. In cycle 1, Rank 0 is in a low power state where the CA domain 202 and data domain 206 are both off. In cycle 2, the CKE0 signal is asserted and causes Rank 0 to power on its CA domain 202 at cycle 3. In cycle 8, the read command (Rd R0) causes Rank 0 to power on its data domain 206 such that both the CA domain 202 and data domains 206 are now powered on between cycles 13-18. In cycle 12, a precharge command (Pre R0) causes Rank 0 to power off its data domain 206 in cycle 19. In cycle 21, the CKE0 signal is de-asserted and causes Rank 0 to power off its CA domain 202 in cycle 22. As a result, Rank 0 is back in a low power state between cycles 22-28.

The power states for Rank 1 are now explained. In cycle 1, the devices in rank 1 are in a low power state where the CA domain 202 and data domain 206 are both off. In cycle 8, the CKE1 signal is asserted and causes Rank 1 to power on the CA domain 202. In cycle 14, a read command (Rd R1) causes Rank 1 to power on its data domain 206 such that both the CA domain 202 and data domain 206 are now powered on between cycles 19-24. In cycle 18, no command (Nop) is received via the CA link, which causes Rank 1 to power off the data domain 206 in cycle 25. The CA domain 202 remains on from cycles 25-28 because CKE1 was never de-asserted.

The power states for the memory controller 102 are now explained. In cycle 1, the memory controller 102 is in low power state where the CA 252 and data domains 256 are both off. Between cycles 3-12, the CA domain 252 is powered on so that the memory controller 102 can transmit commands via the CA link. The power state of the CA domain may be tied to the CKE signals such that anytime a CKE signal is asserted, the CA domain 252 of the controller 102 is powered on. Between cycles 13-24, both the CA 252 and data domains 256 are powered on. The data domain 256 is powered on to allow for data transfer via the DQ link. In cycles 25-28, the data domain 256 is powered off because the data transfer is complete, but the CA domain is still powered on because CKE1 is asserted.

Referring to FIG. 6B, shown is a timing diagram for a memory controller 102 and memory devices 106 that support four power states. The “low” power state corresponds to power state 501 from FIG. 5. The “data only” power state corresponds to power state 504. The “CA only” power state corresponds to power state 505. The “CA & Data” on power state corresponds to power state 508. Although not all four power states are shown to occur within a single memory device 106 or memory controller 102, it is understood that each memory device 106 or memory controller 102 is capable of supporting these four power states.

FIG. 6B is similar to FIG. 6A, except that the CKE0 signal is now de-asserted at cycle 13. As a result, the CA power domain 202 in Rank 0 is powered off at cycle 13 and introduces a new power state from cycles 13-18 where the data domain 206 is powered on but the CA power domain 202 is powered off. The power states for Rank 1 and the memory controller 102 remain the same.

Referring to FIG. 6C, shown is a timing diagram for a memory controller 102 and memory devices 106 that support six power states. The “low” power state corresponds to power state 501 from FIG. 5. The “read data only” power state corresponds to power state 502. The “write data only” power state (not shown) corresponds to power state 503. The “CA only” power state corresponds to power state 505. The “CA and read data on” power state corresponds to power state 506. The “CA and write data on” power state corresponds to power state 507. Although not all six power states are shown to occur within a single memory controller 102 or memory device 106, it is understood that each memory controller 102 or memory device 106 is capable of supporting these six power states.

Referring first to the power states of Rank 0, the Rd R0 command causes the read data domain 216 of Rank 0 to be powered on during cycles 13-18 without causing the write data domain 218 to be powered on. Leaving the write data domain 218 powered off results in additional power savings because the circuitry in the write data domain 218 is not needed during read operations. The remaining power states are the same as the power states from FIG. 6B.

Referring next to the power states of Rank 1, the Wr R1 command causes the write data domain 218 of rank 1 to be powered on during cycles 19-24 without causing the read data domain 216 to be powered on. Leaving the read data domain 216 powered off results in additional power savings because the circuitry in the read data domain 216 is not needed during write operations. The remaining power states are the same as the power states from FIG. 6B.

Referring to the power states of the memory controller 102, the CA domain 252 is powered on between cycles 3-28 to allow the controller 102 to transmit commands via the CA link. The read data domain 266 is powered on between cycles 13-18 to allow the controller 102 to read data from rank 0. However, because data is not being written to any memory ranks during cycles 13-18, the write data domain 268 remains powered off. The write data domain 268 is powered on between cycles 19-24 to allow the controller 102 to write data to rank 1. However, because data is not being read from any memory ranks during this period of time, the read data domain 266 remains powered off.

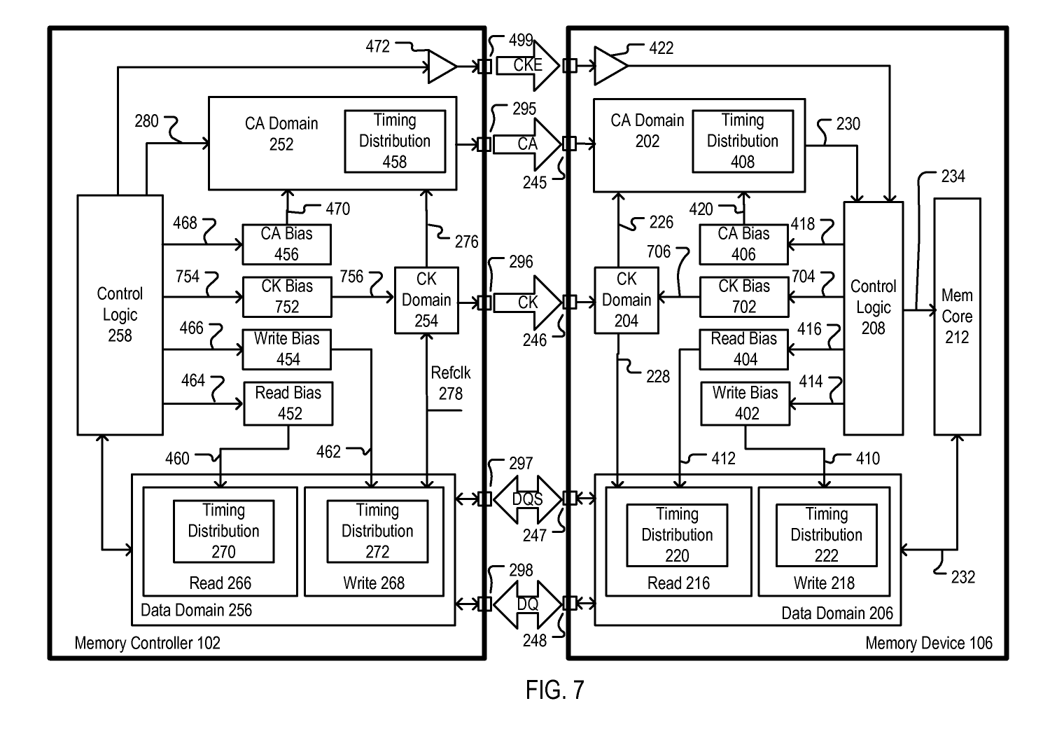

FIG. 7 is a more detailed view of the memory controller 102 and memory device 106 from FIG. 1, according to another embodiment. The memory device 106 in FIG. 7 is similar to the memory device 106 from FIG. 4, but now includes a CK bias circuit 702 that provides a bias voltage 706 to the CK domain 204. The memory controller 102 in FIG. 7 is similar to the memory controller 102 from FIG. 4, but now includes a CK bias circuit 752 that provides a bias voltage 756 to the CK domain 254.

The control logic 208 in memory device 106 generates a control signal 704 that controls the CK bias circuit 702. The CK bias circuit 702 is enabled whenever any of the other bias circuits are enabled, and is disabled when all the other bias circuits are disabled. In other words, the CK domain 204 is powered on whenever any of the other power domains are powered on. For example, the control signal 704 may be generated as the logical-OR of the other control signals 418, 416 and 414. In some embodiments, the CK bias circuit may be not be disabled until some amount of time after the other bias circuits are disabled.

Powering off the bias voltage to the CK domain 204 allows for a further reduction of power consumption. For example, the memory device 106 typically only needs a clock signal when receiving commands or when transferring data. In other situations, the CK domain 204 can be powered down to reduce the power consumption of the memory device 106.

The control logic 258 in memory controller 102 generates a control signal 754 that controls the CK bias circuit 752. The CK bias circuit 752 is enabled whenever any of the other bias circuits are enabled, and is disabled when all the other bias circuits are disabled. In other words, the CK domain 254 is powered on whenever any of the other power domains are powered on. For example, the control signal 754 may generated as the logical-OR of the other control signals 458, 456 and 454. In some embodiments, the CK bias circuit may be not be disabled until some amount of time after the other bias circuits are disabled.

### Circuit Level View of Power Domains

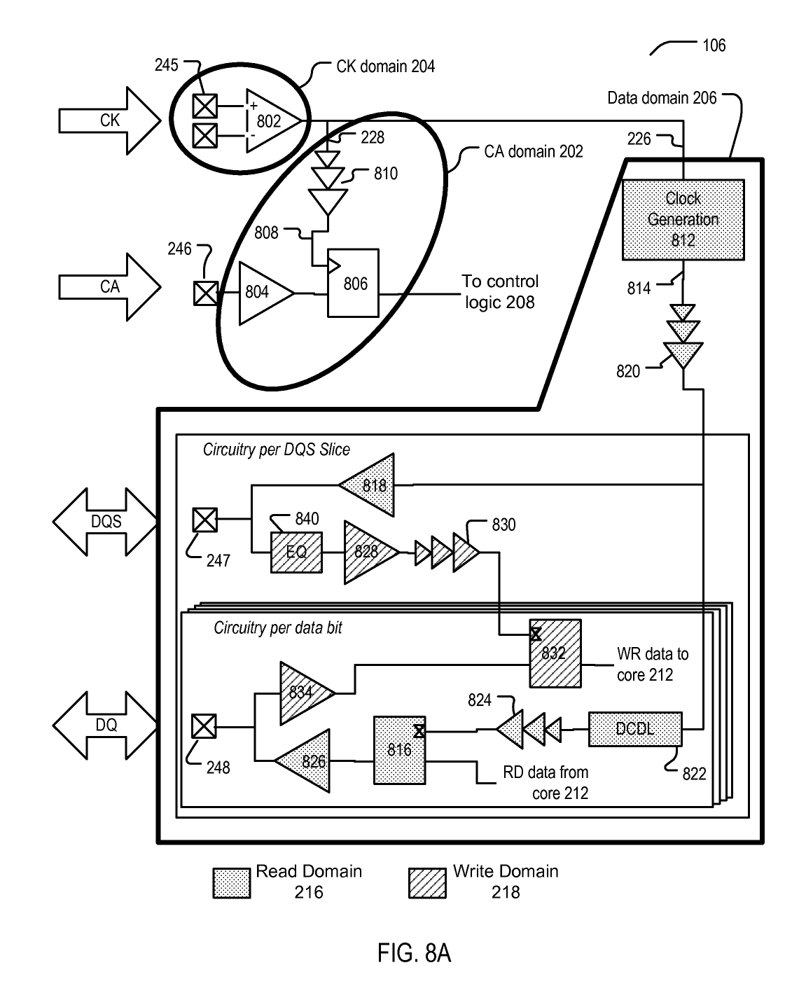

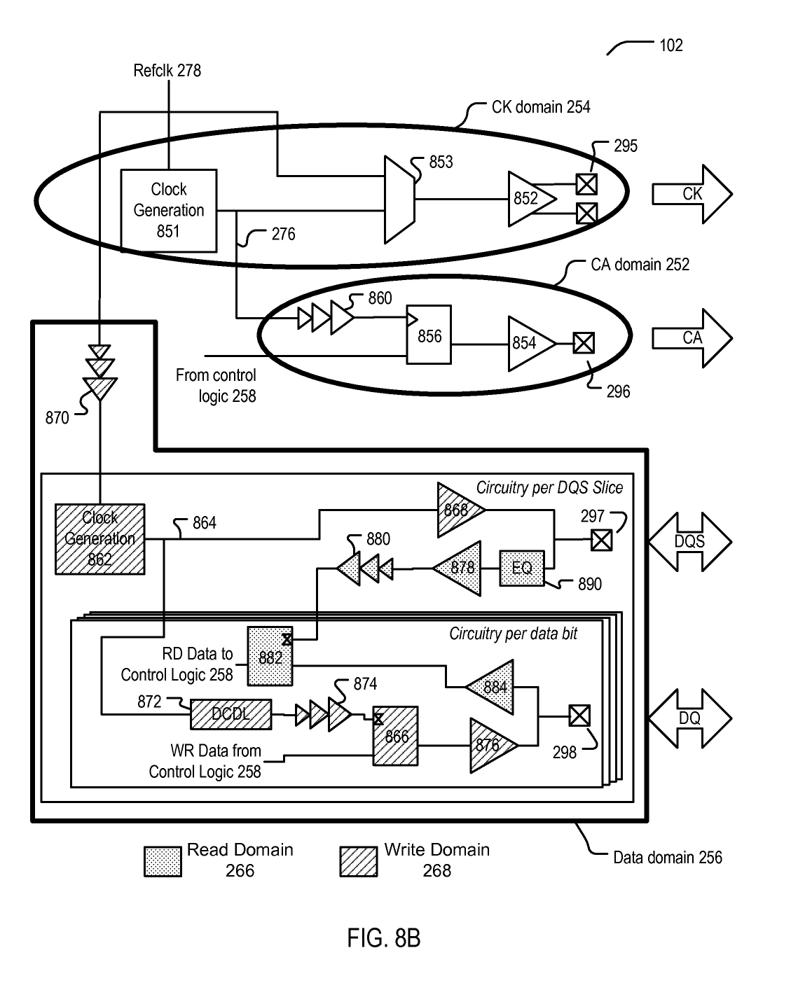

FIG. 8A is a more detailed view of the power domains of a memory device 106, according to an embodiment. Generally speaking, a clock signal is received by the clock domain 204, which is used as a timing reference by the CA domain 202 for receiving incoming commands. The data domain uses clock 226 as a reference in order to generate the frequency and phase of an adjusted clock 814, which is used as a timing reference during read operations.

The CK domain 204 includes a differential receiver circuit 802 that interfaces with the CK link for receiving an external clock signal. The differential receiver circuit 802 then outputs a clock signal 228 to the CA domain 202 and a clock signal 226 to the data domain 206. In some embodiments, the differential receiver circuit 802 may also output a clock signal to the memory core 212 via a separate signaling path (not shown).

The CA domain 202 includes a receiver circuit 804 that interfaces with the CA link for receiving incoming CA signals. The CA domain 202 also includes a clock buffer 810 that receives a clock signal 228 from the receiver 802 and outputs a buffered clock signal 808 to the synchronous logic circuit 806 (e.g., a flip-flop). Synchronous logic circuit 806 uses the clock signal 808 as a timing reference in reading incoming CA signals from the receiver circuit 804. Synchronous logic circuit 806 also outputs the CA to the control logic 208. In one embodiment, receiver 804 and synchronous logic circuit 806 can be viewed as interface circuits for conveying CA information from the CA port(s) 246 to the control logic 208.

The data domain 206 is divided into a read domain 216 and a write domain 218. The read domain 216 includes a clock generation circuit 812, buffer chains 820 and 824, transmitter circuits 816 and 818, DCDL 822 and synchronous logic 816. The clock generation circuit 812 receives a clock signal 226 and generates a clock signal 814 of a different frequency (e.g., by multiplying the clock). For example, the CK link may operate at 400 MHz, while the DQS link operates at 1.6 GHz. The clock generation circuit 812 thus increases the speed of the CK clock by 4× to allow the CK and DQS links to operate at different speeds. In some embodiments, the clock generation circuitry 812 adjusts the phase of the adjusted clock 814, for example, to compensate for delay caused by the clock buffer 820. In some embodiments, the clock generation circuit 812 is an injection locked oscillator (ILO), multiple injection locked oscillator (MILO), phase locked loop (PLL), or delay locked loop (DLL).

The output of the clock generation circuit 812 is an adjusted clock signal 814 that can be transmitted by the transmitter circuit 818 via the DQS link as a data strobe signal. The adjusted clock signal 814 can also be used as a timing reference by synchronous logic circuit 816 during read operations.

The clock path between the clock generation circuit 812 and the synchronous logic circuit 816 includes clock buffer chains 820 and 824 and DCDL 822. In one embodiment, each buffer chain comprises a number of clock buffers coupled in series, wherein the clock buffers are smaller in size at the input side and increase in size toward the output side. This configuration is useful for generating a clock signal which can drive a large load. The DCDL 822 allows for arbitrary phase alignment between the data strobes transmitted via the DQS link and the corresponding data transmitted via the DQ link.

Synchronous logic circuit 816 uses a clock signal provided by the buffer 824 as a timing reference for controlling the flow of data through the circuit 816. During read operations, synchronous logic circuit 816 receives read data from the memory core via an input of the circuit 816. The circuit 816 also outputs the data to the transmitter circuit 826 via an output of the circuit 816. Transmitter circuit 826 interfaces with the DQ link and outputs the read data via the DQ link. In one embodiment, synchronous logic circuit 816 and transmitter 826 can be viewed as interface circuits for conveying data from the core 212 to the data port(s) 248.

The write data domain 218 includes an equalizer 840, an amplifier 828, a buffer chain 830, synchronous logic circuit 832, and receiver circuit 834. The receiver circuit 834 interfaces with the DQ link. During write operations, the receiver 834 receives write data via the DQ link and provides the write data to the synchronous logic circuit 832. In some embodiments, there may be an additional equalizer circuit between the receiver 834 and the data port(s) 248 for equalizing data signals.

Also during write operations, in some embodiments the equalizer 840 equalizes a data strobe signal received via the DQS link. In some embodiments the equalizer 840 passes the data strobe to amplifier 828 that amplifies the data strobe. The amplified data strobe is then provided to a buffer chain 830 that distributes the data strobe to the synchronous logic circuit 832.

Synchronous logic circuit 832 uses a clock signal provided by the buffer 830 as a timing reference for controlling the flow of data through the register 832. During write operations, synchronous logic circuit 832 receives write data from receiver circuit 834. The synchronous logic circuit 832 also outputs the incoming write data to the memory core 212 so that the data can be stored in the memory core 212. In one embodiment, synchronous logic circuit 832 and receiver 834 can be viewed as interface circuits for conveying data from the data port(s) 248 to the core 212.

In some embodiments, one or more of the circuits shown in FIG. 8A may be implemented with CML and turned on and off with a bias voltage. Alternatively, the circuits may be implemented with CMOS. Referring to both FIG. 7 and FIG. 8A, in one embodiment, the timing distribution circuit 220 is comprised of buffer chains 820 and 824 and DCDL 822. In one embodiment, the timing distribution circuit 222 is comprised of parts or all of buffer chain 830. In one embodiment, timing distribution circuit 408 is comprised of parts or all of buffer chain 810.

FIG. 8B is a more detailed view of the power domains of a memory controller 106, according to an embodiment. Generally speaking, the clock domain 254 receives the reference clock (refclk) 278 and an adjusted clock 276. The adjusted clock 276 is output via the CK link, and also used as a timing reference by the CA domain for outputting commands via the CA link. The data domain 256 also uses as a reference clock 278 to generate the frequency and phase of clock 864 and uses the adjusted clock 864 as a timing reference during write operations.

The CK domain 254 includes a clock generation circuit 851 that receives the reference clock 278 and uses the reference clock 278 in generating the frequency and phase of an adjusted clock 276. For example, the reference clock 278 may be 100 MHz, and the clock 276 generated by the clock generation circuit 851 may be 400 MHz. Multiplexer 853 allows the controller 102 to select between outputting either the reference clock 278 or the adjusted clock 276. Transmitter 852 interfaces with the CK link and outputs either the reference clock 278 or the adjusted clock signal 276 via the CK link.

The CA domain 252 includes a buffer chain 860 that receives the adjusted clock signal 276. The buffer chain 860 distributes the adjusted clock signal 276 to the synchronous logic circuit 856 for use as a timing reference in receiving CA information from the control logic and outputting the CA information to the transmitter 854. Transmitter 854 interfaces with the CA link and transmits the commands via the CA link. In one embodiment, synchronous logic circuit 856 and transmitter 854 can be viewed as interface circuits for conveying CA information from the control logic 258 to the CA port(s) 296.

The data domain 256 is divided into a read domain 266 and a write domain 268. The write domain 268 includes a clock generation circuit 862, buffer chains 870 and 874, transmitter circuits 868 and 876, DCDL 872, synchronous logic circuit 866, and transmitter circuit 876. The buffer chain 870 buffers the reference clock 278 at the input to the clock generation circuit 862. The clock generation circuit 862 then generates an adjusted clock signal 864 that may be of a different frequency and phase than the reference clock 278. For example, if the reference clock 278 is 100 MHZ, the adjusted clock 864 may be 1600 MHz. The clock generation circuit 862 may also adjust the phase of the adjusted clock 864 when compared to the reference clock 278. In some embodiments, the clock generation circuit 862 is an injection locked oscillator (ILO), multiple injection locked oscillator (MILO), phase locked loop (PLL), or delay locked loop (DLL).

The DQS transmitter circuit 868 interfaces with the DQS link and transmits the adjusted clock signal 864 as a data strobe signal via the DQS link. The adjusted clock signal 864 is also be used as a timing reference by synchronous logic circuit 866 during write operations.

The clock path between the clock generation circuit 862 and the synchronous logic circuit 866 includes DCDL 872 and buffer chain 874 that together distribute the adjusted clock 864 to the synchronous logic circuit 866. Synchronous logic circuit 866 uses a clock signal provided by the buffer 874 as a timing reference for controlling the flow of data through the synchronous logic circuit 866. During write operations, synchronous logic circuit 866 receives write data from the control logic 258 and outputs the data to the transmitter circuit 876. Transmitter circuit 876 interfaces with the DQ link and outputs the write data via the DQ link. In one embodiment, synchronous logic circuit 866 and transmitter 876 can be viewed as interface circuits for conveying data from the control logic 258 to the data port(s) 298.

The read domain 266 includes an equalizer 890, an receiver 878, a buffer chain 880, synchronous logic circuit 882, and receiver circuit 884. The receiver circuit 884 interfaces with the DQ link. During read operations, the receiver 884 receives read data via the DQ link and provides the read data to the synchronous logic circuit 882. In some embodiments, there may be an additional equalizer circuit between the receiver 884 and the data port 298 for equalizing data signals.

Also during read operations, the equalizer 890 equalizes a data strobe signal received via the DQS link. The equalizer 890 passes the data strobe to the receiver 878 that may amplify the data strobe. The amplified data strobe is then provided to a buffer chain 880 that distributes the data strobe signal to the synchronous logic circuit 882. Synchronous logic circuit 882 uses a data strobe signal provided by the buffer 880 as a timing reference for controlling the flow of data through the synchronous logic circuit 882. The synchronous logic circuit 882 receives read data from the receiver circuit 884. Synchronous logic circuit 882 then outputs the read data to the control logic for further processing by the control logic 258. In one embodiment, synchronous logic circuit 882 and receiver 884 can be viewed as interface circuits for conveying read data from the data port(s) 298 to the control logic 258.

In some embodiments, one or more the circuits shown in FIG. 8B may be implemented with CML and turned on and off with a bias voltage. Alternatively, the circuits may be implemented with CMOS. Referring to both FIG. 7 and FIG. 8B, in one embodiment, the timing distribution circuit 270 is comprised of buffer chain 880. In one embodiment, the timing distribution circuit 272 is comprised of buffer chain 874 and DCDL 872. In one embodiment, timing distribution circuit 458 is comprised of buffer chain 860.

### Bias Supply Circuit

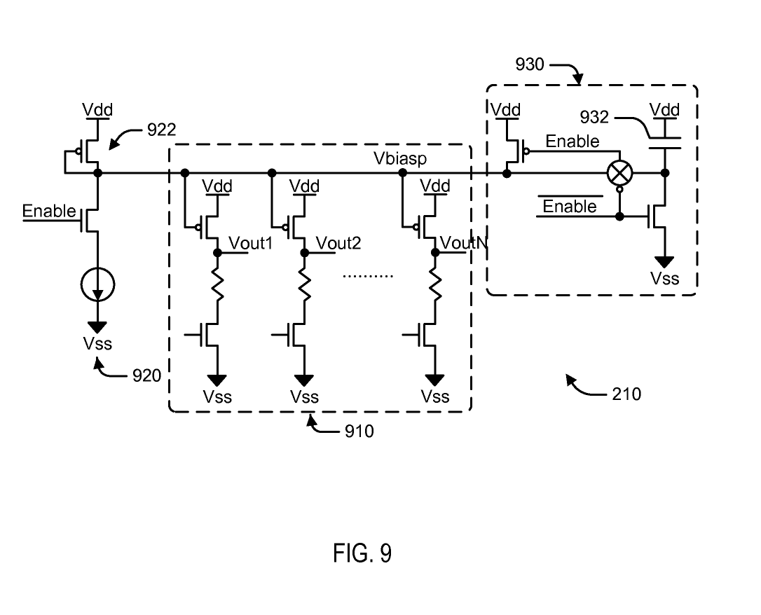

FIG. 9 is a circuit diagram of a bias supply circuit 210 that enables fast turn on of the power domains described herein, according to an embodiment. The bias circuit 210 includes a current source 920 that is selectively enabled by the “Enable” signal to generate, along with a diode connected PMOS device 922, a voltage at the bias voltage node Vbiasp. A plurality of outputs 910, enabled by the bias voltage node Vbiasp, mirror a current at the current source 920. The output nodes Vout1, Vout2 and VoutN may be coupled to one or more nodes of a circuit (not shown) associated with the bias circuit 210. A control circuit 930 selectively couples a capacitor 932 to the network.

Under normal operating conditions (Enable=“1”), the bias node Vbiasp is at a voltage between the supply rails Vdd, Vss. During power down (Enable=“0”), Vbiasp is pulled to Vdd, which in turn disables the outputs 910 (Vout1, Vout2, VoutN). The current source 920 may also be turned off to complete a power down of the circuit. The “power on” time, being the time required for the node Vbiasp to transition from Vdd to the given operating voltage, is dependent upon the total capacitance at the node and the value of the current source 920 as well as the characteristics of the diode connected PMOS device 922. The “power on” time can be decreased by increasing operating power or the current at the current source 920 when the bias circuit 210 is initially powered on.

The control circuit 930 selectively couples the capacitor 932 to the network according to the “Enable” signal. In this manner, the capacitor 932 has zero volts on the lower terminal during power down, and, during power-up, is coupled to the bias node Vbiasp. Thus, upon startup, the charge on Vbiasp is shared with the charge on the capacitor 932, thus bringing the voltage at the bias node Vbiasp toward the operating point voltage. As a result of this charge-sharing, the final operating voltage can be obtained more quickly, with minimal impact upon normal operation, while simultaneously reducing a surge of supply current to the bias circuit 210.

In order to configure the control circuit 930 and capacitor 932 to achieve the operating voltage, the value of operating voltage for the bias node Vbiasp is first obtained. The total capacitance C for the node, including any residual capacitance exhibited by the circuit components, is obtained by measurement or estimation. The total capacitance C may then be divided into two domains in the power-down state: a first portion of C may be pulled to Vdd during power-down, while a second portion is pulled to Vss during power down. The domains are separated in the power-down state by the control circuit 930, which isolates them via a passgate structure. The domains may be configured to be proportional to the desired operating voltage, such that, when the domains are combined upon startup of the circuit 210 (the control circuit 930 enables the path at Vbiasp), a voltage approximating or matching the operating voltage appears at the bias node Vbiasp.

A “charge share” may be effected between the capacitor 932 and the capacitance at the bias node Vbiasp opposite the control circuit 930. Given two identical capacitors, if the first capacitor is charged to 1.2V, the second is completely discharged (to 0V), and the two are shorted together via a switch, the resultant voltage will be 0.6V, or halfway between the two capacitors' initial voltages. The charge on the first capacitor is “shared” to the second and since they are identical, the initial charge gets split equally. If the first capacitor is twice as large as the second, then the resultant voltage will be ⅔ of the initial voltage or 0.8V. Similarly, if the second is three times as large as the first, the final voltage will be ¼ of the 1.2V or 0.3V. By adjusting the ratio of capacitance, one can obtain a desired non-rail voltage.

Thus, with respect to the capacitor 932, the capacitance value of the capacitor 932 may be selected based on the proportional capacitance to be achieved as described above. In particular, the capacitor 932 may be configured as a portion of the total capacitance C that is pulled to Vdd during power down. When the Enable signal is asserted to initiate power-up of the bias circuit 210, the two domains combine (“charge share”) to produce the desired operating voltage at Vbiasp. In some embodiments binary weighted capacitor sizes may be selected to achieve the right capacitance ratio.

During power-down, all nodes are pulled to supplies and hence only consume current from device leakage, which may be quite low, and is approximately the same as the leakage of the same capacitance used as bias bypass capacitance. Other supply voltages, if available, may also be employed to optimize start-up time, current surge reduction, silicon area or other design considerations. The additional circuitry can be implemented in parallel to the existing bias circuitry. It may be beneficial to add additional capacitance to the bias node Vbiasp to achieve the target proportion of capacitance at the two domains. For example, a circuit implementation may present obstacles to dividing a node between the two domains during power-down, necessitating the additional capacitance.

Further, the bias node Vbiasp may benefit from additional capacitance to increase noise immunity. By referencing both domains of the total capacitance C to either supply (Vdd, Vss), operational noise within the circuit 210 may be minimized. However, the circuit 210 may be configured to “charge share” at power-up as described above, and then disconnect some or all of the capacitance (e.g., capacitor 932) after a specified time or when the desired operating voltage is obtained.

For those cases where the desired operating point is a substantial portion of the supply, a single capacitor as shown may be sufficient to obtain (or approximate) the operating point within an acceptable time. When the operating point requires greater accuracy, or is dependent on characteristics of the circuit a number of alternative configurations to the bias circuit may be implemented. For example, an initial sharing may be conducted as described above, to an approximate voltage, followed by a period of normal active feedback control circuit operation to pull in the exact value. In this period the active circuitry consisting of the diode-configured PMOS device 922 and the current source 920 pull the bias node Vbiasp to the precise final value. Alternatively, an auto-adjust circuit may be employed to switch in more or less capacitance to compensate, in real time, for a change from the initial conditions. For example, just before a power-up sequence, the amount of capacitance may be adjusted in response to observation of the supply voltage, temperature, or some other circuit or environmental condition as well as the desired bias voltage. Further, a circuit may be implemented to perform a calibration that effectively measures change at the bias node and then adjusts the capacitance for the next power-up sequence.

Because the operating voltage and/or the capacitance of a bias node (e.g., bias node Vbiasp) may be dependent on manufacturing variations, or variations due to operating voltage or temperature, it may not be possible, during initial design of a bias circuit, to configure the capacitances of each domain to effect a “charge share” to obtain an exact voltage at power-on of the bias circuit. In such a case, a capacitance ratio can be selected to minimize startup time across corners. Alternatively, an additional bias circuit (not shown) omitting a control circuit may be employed in conjunction with the bias circuit 210, where the bias circuit 210 obtains an approximate of the operating point and the additional bias circuit transitions to the operating point with greater accuracy. In still further embodiments, a bias circuit may employ a programmable capacitance ratio, which may be adjusted automatically based on a comparison with a replica circuit, or may be adjusted periodically under settings maintained at a register. Adjustable bias circuits may be configured to compensate for changes in capacitance or other circuit characteristics resulting from the fabrication process, supply voltage or temperature of the bias circuit.

Embodiments of the disclosed memory system thus reduce power consumption by dividing components of the system into different power domains that are operated in different power states. Some of the power domains may include timing signal distribution circuitry that can be selectively powered on when their output is needed and powered off when their output is not needed. Bias supply circuits provide the bias voltages to the power domains and can be switched on in a short amount of time to avoid adding additional latency to memory accesses.

Upon reading this disclosure, those of skill in the art may appreciate still additional alternative designs for reducing power consumption in a memory system. Thus, while particular embodiments and applications of the present disclosure have been illustrated and described, it is to be understood that the disclosure is not limited to the precise construction and components disclosed herein. Various modifications, changes and variations which may be apparent to those skilled in the art may be made in the arrangement, operation and details of the method and apparatus of the present disclosure herein without departing from the spirit and scope of the disclosure as defined in the appended claims.

What is claimed is:

1. A memory device comprising:
a memory core;
data interface circuitry to transfer data between the memory core and one or more ports of the memory device;
distribution circuitry to distribute a timing reference signal to the data interface circuitry; and
control circuitry to power on the distribution circuitry in response to a memory access command that specifies access to the memory core.

2. The memory device of claim 1, wherein the distribution circuitry comprises current mode logic (CML) distribution circuitry and further comprising:
bias circuitry to generate a bias voltage for the CML distribution circuitry, and
wherein the control circuitry powers on the distribution circuitry by powering on the bias voltage for the CML distribution circuitry.

3. The memory device of claim 1, further comprising:
a clock generation circuit to generate the timing reference signal,
wherein the distribution circuitry distributes the timing reference signal generated by the clock generation circuit to the data interface circuitry, and
wherein the control circuitry also powers on the clock generation circuit in response to the memory access command.

4. The memory device of claim 1, wherein the distribution circuitry comprises at least one of a clock buffer or a digitally controlled delay line (DCDL) that is powered on by the control circuitry in response to the memory access command.

5. The memory device of claim 1, wherein the memory access command is at least one of a read command for reading data from the memory core, a write command for writing data to the memory core, a row access command for accessing a row of the memory core, or a column access command for accessing a column of the memory core.

6. The memory device of any of claim 1, wherein the control circuitry powers off the distribution circuitry after a data transfer corresponding to the memory access command is complete.

7. The memory device of claim 6, wherein the control circuitry powers off the distribution circuitry in response to at least one of a pre-charge command, failing to receive an additional memory access command after the memory access command is received, or an explicit power down indication in the memory access command.

8. The memory device of claim 1, wherein
the data interface circuitry comprises read interface circuitry to convey read data from the memory core to the one or more ports during read operations and write interface circuitry to convey write data from the one or more ports to the memory core during write operations;
the distribution circuitry comprises first distribution circuitry to distribute a timing reference signal to the read interface circuitry and second distribution circuitry to distribute a timing reference signal to the write interface circuitry; and
the control circuitry selectively powers on either the first distribution circuitry or the second distribution circuitry based on whether the memory access command is a read command or a write command, respectively.

9. The memory device of claim 1, further comprising:
command and address (CA) interface circuitry to convey CA signals from one or more CA ports of the memory device to the control circuitry; and
additional distribution circuitry to distribute a timing reference signal to the CA interface circuitry; and
wherein the control circuitry powers on the additional clock distribution circuitry in response to an external control signal.

10. A method of operation in a memory device that includes a memory core and data interface circuitry to transfer data between the memory core and one or more ports of the memory device, the method comprising:
receiving a memory access command that specifies access to the memory core;
in response to the memory access command, powering on distribution circuitry that distributes a timing reference signal to the data interface circuitry of the memory device.

11. The method of claim 10, wherein powering on the distribution circuitry in response to the memory access command comprises:
selectively powering on either first distribution circuitry or second distribution circuitry based on whether the memory access command is a read command or a write command, respectively,
wherein the first distribution circuitry distributes a timing reference signal to read interface circuitry that conveys read data from the memory core to the one or more ports of the memory device, and
wherein the second distribution circuitry distributes a timing reference signal to write interface circuitry that conveys write data from the one or more ports of the memory device to the memory core.

12. The method of claim 10, further comprising:
receiving an external signal; and
powering on additional distribution circuitry in response to the external signal, the additional distribution circuitry distributing a timing reference signal to command and address (CA) interface circuitry that conveys CA signals from one or more CA ports of the memory device to control circuitry of the memory device; and
wherein receiving the memory access command comprises receiving the memory access command via the CA interface circuitry.

13. A memory controller comprising:
control circuitry;
data interface circuitry to transfer data between the control circuitry and one or more ports of the memory controller; and
distribution circuitry to distribute a timing reference signal to the data interface circuitry;
wherein the control circuitry powers on the distribution circuitry if data is to be transferred in a memory access operation.

14. The memory controller of claim 13, wherein the distribution circuitry comprises current mode logic (CML) distribution circuitry, and further comprising:
bias circuitry to generate a bias voltage for the CML distribution circuitry, and
wherein the control circuitry powers on the distribution circuitry by powering on the bias voltage for the CML distribution circuitry.

15. The memory controller of claim 13, further comprising:
clock generation circuitry to generate the timing reference signal, wherein the distribution circuitry distributes the timing reference generated by the clock generation circuit to the data interface circuitry, and
wherein the control circuitry also powers on the clock generation circuit if data is to be transferred in a memory access operation.

16. The memory controller of claim 13, wherein the distribution circuitry comprises at least one of a clock buffer or a digitally controlled delay line (DCDL) that is powered on by the control circuitry if data is to be transferred in a memory access operation.

17. The memory controller of claim 13, wherein the control circuitry powers off the distribution circuitry if a data transfer corresponding to the memory access operation is complete.

18. The memory controller of claim 17, wherein the control circuitry powers off the distribution circuitry after the data transfer is complete and no other memory access operations are pending.

19. The memory controller of claim 13, wherein:
the data interface circuitry comprises read interface circuitry to convey read data from the one or more ports to the control circuitry during read operations and write interface circuitry to convey write data from the control circuitry to the one or more ports during write operations;
the distribution circuitry comprises first distribution circuitry to distribute a timing reference signal to the read interface circuitry and second distribution circuitry to distribute a timing reference signal to the write interface circuitry; and
the control circuitry selectively powers on either the first distribution circuitry or the second distribution circuitry responsive to whether data is to be read or written during a memory access operation, respectively.

20. The memory controller of claim 13, further comprising:
command and address (CA) interface circuitry to convey CA signals from the control logic to one or more CA ports of the memory controller; and
additional distribution circuitry to distribute a timing reference signal to the CA interface circuitry, and
wherein the control circuitry powers on the additional distribution circuitry if memory access commands are to be issued.
